(19) United States
(12) Patent Application Publication
(10) Pub. No.: US 2026/0190328 A1
(43) Pub. Date: Jul. 2, 2026

(54) APPARATUS COMPRISING A DOPED EPITAXIAL SILICON MATERIAL AND RELATED METHODS

(71) Applicant: Micron Technology, Inc., Boise, ID (US)

(72) Inventors: Protyush Sahu, Boise, ID (US); Madhana Sunder, Meridian, ID (US); Jesse Wensel, Boise, ID (US); Wenyi Hou, Taichung (TW); Jeffery B. Hull, Boise, ID (US); Eric E. Kron, Meridian, ID (US)

(21) Appl. No.: 19/413,346

(22) Filed: Dec. 9, 2025

Related U.S. Application Data
(60) Provisional application No. 63/739,316, filed on Dec. 27, 2024.

(51) Int. Cl. H10B 12/00

(52) U.S. Cl. CPC H10B 12/482; H10B 12/02; H10B 12/485; H10B 12/488

(57) ABSTRACT

An apparatus comprising a memory array comprising word lines, bit lines, and memory cells, one or more of the memory cells coupled to an associated word line and an associated bit line and comprising active areas and shallow trench isolation (STI) structures adjacent to a base material. The word lines are in the active areas and STI structures and bit line structures are adjacent to the active areas and the STI structures and oriented perpendicular to the word lines. The bit line structures comprise bit lines and bit contacts. Cell contact structures are laterally adjacent to the bit line structures and comprise cell contacts comprising an epitaxial semiconductive material. One or more of the bit contacts and the epitaxial semiconductive material comprise a doped epitaxial silicon material, the doped epitaxial silicon material exhibiting a relatively greater dopant concentration in a [110] crystal orientation than in a [100] or [111] crystal orientation. Methods of forming the apparatus are also disclosed.

### CROSS-REFERENCE TO RELATED APPLICATIONS

This application claims the benefit under 35 U.S.C. § 119(e) of U.S. Provisional Patent Application Ser. No. 63/739,316, filed Dec. 27, 2024, the disclosure of which is hereby incorporated herein in its entirety by this reference.

### TECHNICAL FIELD

This disclosure relates generally to the field of electronic device design and fabrication. More particularly, the disclosure relates to methods of forming apparatus (e.g., electronic devices) including one or more doped epitaxial silicon material having selectively distributed dopants, and to related apparatus.

### BACKGROUND

Electronic device designers desire to increase the level of integration or density of features within an electronic device by reducing the dimensions of individual features and by reducing a separation distance between neighboring features. In addition, electronic device designers often desire to design architectures that are not only compact, but offer performance advantages, as well as simplified designs. A relatively common electronic device is a memory device, which includes a memory array having a number of memory cells arranged in a grid pattern. One type of memory cell is a dynamic random access memory (DRAM) device, which is a volatile memory device that may lose a stored state over time unless the DRAM device is periodically refreshed by an external power supply. In one simple configuration, a DRAM cell includes one access device (e.g., a transistor) and one storage device (e.g., a capacitor). Modern applications for memory devices may utilize vast numbers of DRAM unit cells, arranged in an array of rows and columns. The DRAM cells are electrically accessible through digit lines (e.g., bit lines) and access lines (e.g., word lines) arranged along the rows and columns of the array.

As the dimensions and spacing of the features in the electronic device decrease, the likelihood of electrical shorting between conductive features increases. For instance, as the electronic device decreases in size, electrical shorting occurs between conductive contacts of the electronic device due to decreased contact size and contact spacing. The electrical shorting may lead to failure of the electronic devices and result in a low yield, sometime as low as 40%.

### BRIEF DESCRIPTION OF THE DRAWINGS

FIG. 1 is a simplified, partial cross-sectional view of an apparatus including contact structures according to embodiments of the disclosure;

FIGS. 2A, 2B, 2F, and 2G are simplified, partial cross-sectional views (in the X-Z direction) and FIGS. 2C-2E are simplified, partial top-down views (in the X-Y direction) along the A-A line of FIGS. 1 and 2B, illustrating a method of forming the apparatus according to embodiments of the disclosure;

FIGS. 2F and 2G are simplified, partial cross-sectional views of additional apparatus including contact structures according to embodiments of the disclosure;

FIG. 3 is a simplified flow chart of a method of forming the apparatus according to embodiments of the disclosure;

FIG. 4 is a functional block diagram of an electronic device in accordance with embodiments of the disclosure; and

FIG. 5 is a schematic block diagram of an electronic system in accordance with embodiments of the disclosure.

### DETAILED DESCRIPTION

To reduce electrical shorting between neighboring features (e.g., neighboring conductive features) of an apparatus (e.g., an electronic device, a microelectronic device), a dopant distribution of the features is tailored. The features are formed of and include an epitaxial semiconductive material, such as an epitaxial silicon material. The dopant may be selectively formed (e.g., selectively incorporated) into a desired crystal orientation of the epitaxial semiconductive material while other crystal orientations of the epitaxial semiconductive material include relatively less dopant. By incorporating the dopant predominantly in the desired crystal orientation of the epitaxial semiconductive material, a likelihood of electrical shorting between the neighboring conductive features is reduced relative to a degree of electrical shorting observed between similar neighboring conductive features in conventional apparatus. The epitaxial semiconductive material of one or more of the neighboring features may be a doped epitaxial silicon material. The dopant distribution in the epitaxial silicon material may be tailored by process conditions used in forming the doped epitaxial silicon material. The doped epitaxial silicon material may include the dopant distributed in relatively higher or relatively lower concentrations in different crystal orientations of the epitaxial silicon material. The neighboring conductive features may include contacts (e.g., bit contacts, cell contacts) formed of and including the doped epitaxial silicon material.

The illustrations presented herein are not actual views of any electronic device, or any component thereof, but are merely idealized representations, which are employed to describe embodiments of the invention.

As used herein, the singular forms following “a,” “an,” and “the” are intended to include the plural forms as well, unless the context clearly indicates otherwise.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, any relational term, such as “first,” “second,” “top,” “bottom,” “upper,” “lower,” “above,” “beneath,” “side,” “upward,” “downward,” etc., is used for clarity and convenience in understanding the disclosure and accompanying drawings, and does not connote or depend on any specific preference or order, except where the context clearly indicates otherwise. For example, these terms may refer to an orientation of elements of any electronic device when utilized in a conventional manner. Furthermore, these terms may refer to an orientation of elements of any electronic device as illustrated in the drawings.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “about” or “approximately” used in reference to a given parameter is inclusive of the stated value and has the meaning dictated by the context (e.g., it includes the degree of error associated with measurement of the given parameter, as well as variations resulting from manufacturing tolerances, etc.). For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes an electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co-and Ni-based alloy, an Fe- and Co-based alloy, a Co- and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductive material (e.g., conductively doped epitaxial silicon, conductively doped polysilicon, conductively doped germanium (Ge), conductively doped silicon germanium (SiGe)). In addition, a “conductive structure” means and includes a structure formed of and including a conductive material.

As used herein, “insulative material” means and includes an electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formula are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

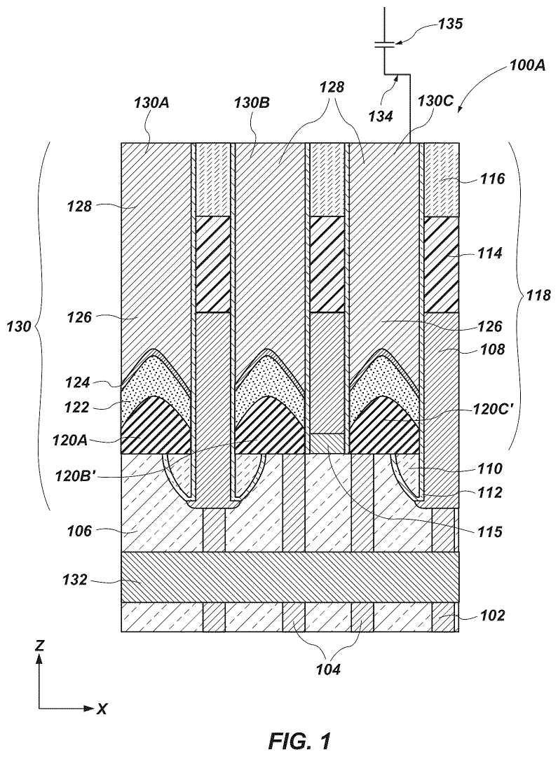

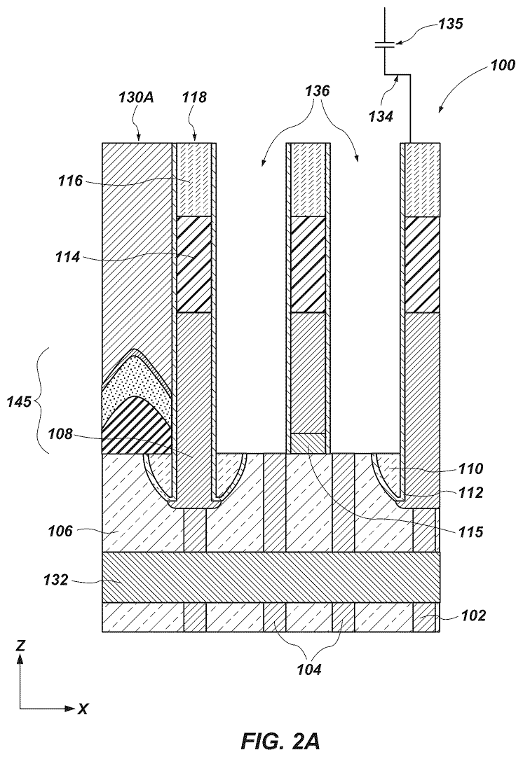

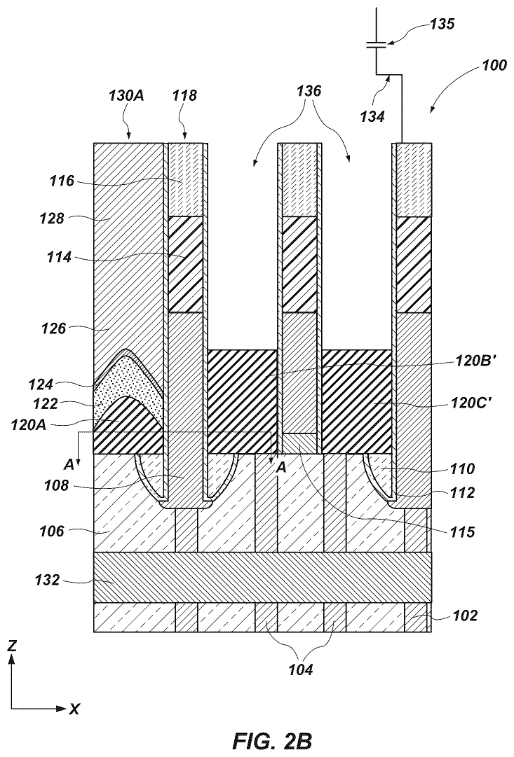

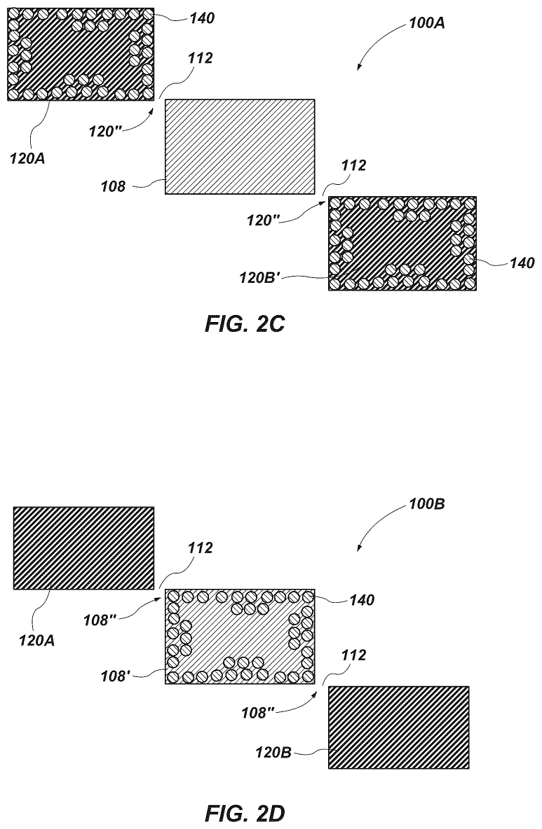

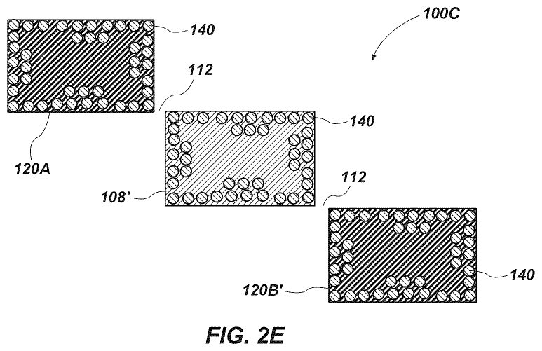

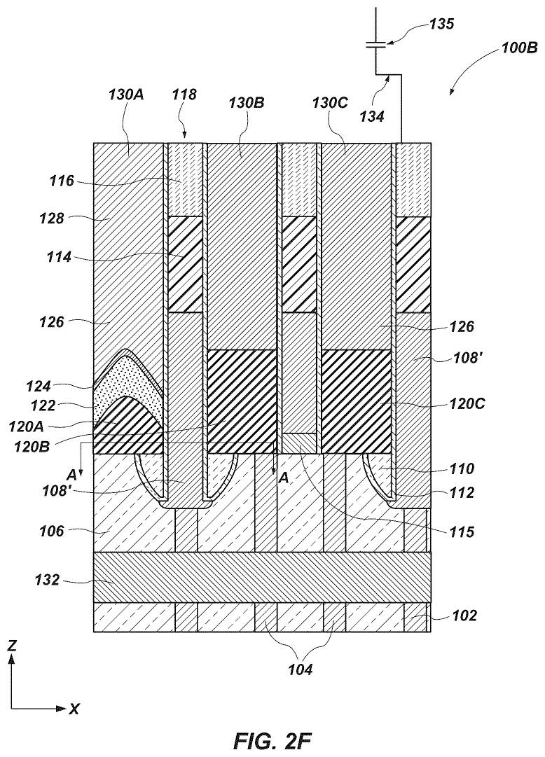

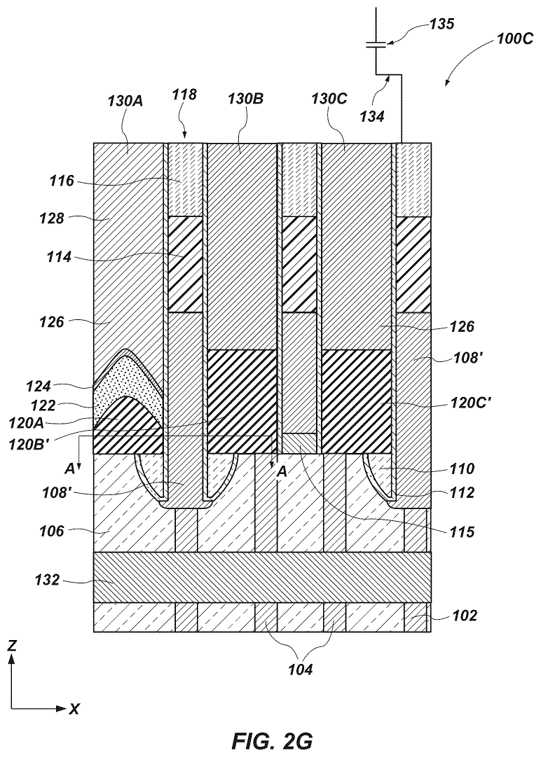

FIG. 1 shows an apparatus 100 (e.g., an electronic device) according to embodiments of the disclosure. The apparatus 100 includes a base material 102 (e.g., a substrate), active areas 104, shallow trench isolation (STI) structures 106, bit contacts 108 (e.g., digit contacts), diffusion regions 110, an insulative material 112 (e.g., an insulative spacer material), bit lines 114, an optional etch stop material 115, one or more insulative cap materials 116, bit line structures 118, an epitaxial semiconductive material 120 (e.g., a monocrystalline semiconductive material, a monocrystalline silicon material), a metal silicide 122, a barrier material 124, a metal material 126, cell contacts 128 (e.g., storage node contacts), and cell contact structures 130. FIG. 1 is a cross-sectional view of the apparatus 100 in a first horizontal direction (e.g., a bit line direction). For convenience in describing FIG. 1, the first horizontal direction is defined as the X-direction and a second horizontal direction, which is transverse (e.g., perpendicular) to the first horizontal direction, is defined as the Y-direction. A third direction, which is transverse (e.g., perpendicular) to each of the first horizontal direction and the second horizontal direction, is defined as the Z-direction. Similar directions are defined in FIGS. 2A-2G. One or more of the bit contact structures 118 and the cell contact structures 130 include the doped epitaxial silicon material. In some embodiments, the epitaxial semiconductive material 120 of the cell contact structures 130 is formed of and includes the doped epitaxial silicon material. In other embodiments, the bit contacts 108 of the bit line structures 118 are formed of and include the doped epitaxial silicon material. In yet other embodiments, both the epitaxial semiconductive material 120 and the bit contacts 108 are formed of and include the doped epitaxial silicon material.

The base material 102 may include a conventional silicon substrate (e.g., a conventional silicon wafer) or another bulk substrate comprising a semiconductive material. In some embodiments, the base material 102 includes different materials, structures, devices, and/or regions formed thereon and/or therein. In some embodiments, the base material 102 includes complementary metal-oxide-semiconductor (CMOS) circuitry and devices configured for effectuating operation of memory cells of the apparatus 100. The active areas 104 and the STI structures 106 may be on or in the base material 102. The active areas 104 are formed of and include monocrystalline silicon, such as doped monocrystalline silicon, and may be isolated from one another by the STI structures 106, which are formed of and include silicon dioxide (SiO₂). By way of example only, the active areas 104 may be formed of n-doped silicon. The diffusion regions 110 may be formed from and include monocrystalline silicon.

The insulative spacer material 112 may be formed of and include an insulative material such as, for example, one or more of an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof), and amorphous carbon. In some embodiments, the insulative spacer material 112 comprises SiO₂.

The bit line structures 118 include the bit lines 114 and the materials (e.g., the bit contacts 108, the insulative cap material 116) vertically adjacent to the bit lines 114. The bit contacts 108 are adjacent to (e.g., vertically adjacent to) the active areas 104 and may be formed of and include one or more electrically conductive materials. The bit contacts 108 may be undoped or doped. The dopant may be an n-type dopant, such as phosphorus, arsenic, antimony, or a combination thereof. In some embodiments, the bit contacts 108 are formed of and include the doped epitaxial silicon material, such as phosphorus doped epitaxial silicon. The bit lines 114 are adjacent to (e.g., vertically adjacent to) the bit contacts 108 and may be formed of and include one or more electrically conductive materials. The insulative cap material 116 is adjacent to (e.g., vertically adjacent to) the bit lines 114 and may be formed of and include one or more electrically insulative materials.

The cell contact structures 130 include the epitaxial semiconductive material 120, the metal silicide 122, the barrier material 124, and the metal material 126. The cell contacts 128 may also include a portion of the metal material 126, which may be formed of and include a conductive material (e.g., an electrically conductive material). The epitaxial semiconductive material 120 is on (e.g., directly on, directly contacts) the active areas 104 and the STI structures 106, as shown in FIG. 1. The epitaxial semiconductive material 120 of the cell contact structures 130 may be an epitaxial silicon material, such as monocrystalline silicon or nanocrystalline silicon, or other epitaxial material with one or more ordered domains. In some embodiments, the epitaxial silicon material exhibits a monocrystalline orientation. The epitaxial semiconductive material 120 may, optionally, include an amorphous silicon (not shown) portion over the epitaxial semiconductive material 120. The epitaxial semiconductive material 120 may be undoped or doped, such as including one or more n-type dopants. The dopant may include, but is not limited to, phosphorus, arsenic, antimony, or a combination thereof. In some embodiments, the epitaxial semiconductive material 120 is doped epitaxial silicon, such as phosphorus doped epitaxial silicon.

The metal silicide 122 is adjacent to (e.g., on or over) the epitaxial semiconductive material 120, the barrier material 124 is on (e.g., directly on, directly contacts) the metal silicide 122, and the metal material 126 of the cell contact 128 is on (e.g., directly on, directly contacts) the barrier material 124. The metal silicide 122 may be formed of and include an electrically conductive material. The cell contact structures 130 separate adjacent bit line structures 118 from one another in the first horizontal direction (e.g., the bit line direction). In the second horizontal direction (e.g., a word line direction), the cell contact structures 130 are positioned over the STI structures 106. When the epitaxial semiconductive material 120 is epitaxial silicon, the epitaxial silicon, the metal silicide 122, and the barrier material 124 may constitute an epitaxial plug 145 (e.g., a doped epitaxial plug, such as a phosphorus doped epitaxial plug) between the cell contacts 128 and the bit contacts 108. The epitaxial plug 145 is shown in FIG. 1 as including a non-planar (e.g., rounded) uppermost surface. However, the uppermost surface of the epitaxial plug 145 may be substantially planar (see 120B′, 120C′ in FIGS. 2F and 2G). While FIG. 1 illustrates the epitaxial plug 145 of the cell contact structures 130 as including multiple materials, the epitaxial plug 145 may include fewer or greater numbers of materials than illustrated. For instance, the epitaxial plug 145 may include a single material, such as the epitaxial silicon material 120B′, 120C′ in FIGS. 2F and 2G. For convenience, FIGS. 1-2G illustrate various configurations of the epitaxial plug 145, with the understanding that the apparatus 100 may include a single configuration of the epitaxial plug 145 (e.g., all exhibiting the non-planar (e.g., rounded) uppermost surface or all exhibiting the substantially planar surface) or multiple configurations of the epitaxial plug 145.

The apparatus 100 also includes word lines 132 (e.g., access lines) adjacent to the bit contacts 108. The word lines 132 may be formed of and include an electrically conductive material including, but not limited to, one or more of a metal (e.g., tungsten, titanium, nickel, platinum, gold), a metal alloy, a metal-containing material (e.g., metal nitrides, metal silicides, metal carbides, metal oxides), and a conductively doped semiconductive material (e.g., conductively doped silicon, conductively doped germanium, conductively doped silicon germanium). By way of non-limiting example, the word lines 132 may individually comprise one or more of W, TiN, TaN, WN, TiAlN, Ti, Pt, Rh, Ir, IrOₓ, Ru, RuOₓ, and alloys thereof. In some embodiments, the word lines 132 are formed of tungsten. The word lines 132 are isolated from one another by the STI structures 106 and are oriented perpendicular to the bit lines 114.

Redistribution material (RDM) structures 134 (also referred to as “redistribution layer (RDL) structures”) may be formed on or over the cell contacts 128, and storage node structures 135, such as capacitors, may be in electrical communication with the RDM structures 134 and the cell contacts 128. The RDM structures 134 may be configured to effectively shift (e.g., stagger, adjust, modify) lateral positions (e.g., in the X-direction, in a second horizontal direction, transverse to the X-direction) of the cell contacts 128 to accommodate a desired arrangement (e.g., a hexagonal close packed arrangement) of the storage node structures 135 over and in electrical communication with the cell contacts 128. The RDM structures 134 may be formed of and include one or more electrically conductive materials. The RDM structures 134 may be configured and formulated to couple (e.g., physically couple, electrically couple) the cell contacts 128 of the cell contact structures 130 to the storage node structures 135. The storage node structures 135 may be configured to store a charge representative of a programmable logic state. For example, a charged state of the storage node structures 135 may represent a first logic state (e.g., a logic 1), and an uncharged state of the storage node structures 135 may represent a second logic state (e.g., a logic 0). By way of example only, the cell contacts 128 may correspond to a landing pad for the storage node structures 135. For convenience, only cell contact structure 130C is illustrated as including the RDM structure 134 and the storage node structure 135 in FIG. 1, although it is understood that each of the cell contact structures 130A, 130B may include the RDM structure 134 and the storage node structure 135.

Openings (e.g., contact openings) are defined by sidewalls (e.g., substantially straight, vertical sidewalls without voids or spaces) of the insulative spacer material 112, which is laterally adjacent to the bit contacts 108, the bit lines 114, and the insulative cap material 116. A width of the openings between adjacent portions of the insulative spacer material 112 of the bit line structures 118 may be within a range of from about 4 nm to about 25 nm, such as from about 4 nm to about 6 nm, from about 6 nm to about 8 nm, from about 8 nm to about 10 nm, from about 10 nm to about 15 nm, from about 15 nm to about 20 nm, or from about 20 nm to about 25 nm. In some embodiments, the width may be equal to or less than about 25 nm (e.g., about 10 nm, about 8 nm). The width may be selected and tailored to affect a size and shape of one or more features (e.g., the cell contacts 128, the epitaxial semiconductive material 120B′, 120C′) of the apparatus 100. As the density of features on the apparatus increases and dimensions of the features (e.g., the cell contacts 128) become smaller, the width between opposing portions of the insulative spacer material 112 becomes smaller and smaller. The bit line structures 118 and cell contact structures 130 may, for example, exhibit smaller and smaller dimensions, such as dimensions less than or equal to about 100 nm.

The cell contacts 128 of the cell contact structures 130 may individually exhibit a first height, and a combination of the epitaxial semiconductive material 120, the metal silicide 122, and the barrier material 124 (e.g., constituting the epitaxial plug 145) of the cell contact structures 130 may exhibit a second height that is relatively less than the first height of the cell contacts 128. The first height of the cell contacts 128 is greater than or equal to a combined thickness of additional materials of the cell contact structures 130 underlying the cell contacts 128. Accordingly, the first height corresponds to the vertical thickness of the cell contacts 128 and is relatively greater than the second height of the epitaxial semiconductive material 120, the metal silicide 122, the barrier material 124, and additional materials adjacent thereto. The first height of the cell contacts 128 may be within a range of from about 15 nm to about 200 nm, such as from about 15 nm to about 40 nm, from about 40 nm to about 80 nm, from about 80 nm to about 120 nm, from about 120 nm to about 160 nm, or from about 160 nm to about 200 nm. The second height of the materials of the cell contact structures 130 underlying the cell contacts 128, may be within a range of from about 10 nm to about 65 nm, such as from about 10 nm to about 20 nm, from about 20 nm to about 30 nm, from about 30 nm to about 40 nm, from about 40 nm to about 50 nm, or from about 50 nm to about 65 nm.

FIGS. 2A, 2B, 2F, and 2G are simplified, partial cross-sectional views illustrating embodiments of forming apparatus 100 (e.g., an electronic device, a microelectronic device, a memory device, such as a DRAM device) at different process stages. FIGS. 2C through 2E are simplified partial top-down views along the A-A line of FIG. 2B and show various dopant distributions within the epitaxial silicon materials of one or more of the bit contacts 108 and the epitaxial semiconductive material 120. For instance, the bit contacts 108 may be doped and the epitaxial semiconductive material 120 may be undoped, the epitaxial semiconductive material 120 may be doped and the bit contacts 108 may be undoped, or both the bit contacts 108 and the epitaxial semiconductive material 120 may be doped. The apparatus 100 may include apparatus 100A (see FIG. 1), apparatus 100B (see FIG. 2F), or apparatus 100C (see FIG. 2G), which include different dopant configurations. For convenience in describing FIGS. 2A-2G below, the epitaxial semiconductive material 120 is referred to as doped epitaxial silicon material 120. However, it is understood that the doped epitaxial silicon material may be present in the epitaxial semiconductive material 120, the bit contacts 108, or both the epitaxial semiconductive material 120 and the bit contacts 108.

Dopant 140 may be heterogeneously distributed in sidewalls of the epitaxial silicon materials of one or more of the bit contacts 108 and the epitaxial semiconductive material 120. Relative amounts of the dopant 140 may vary throughout different portions of the epitaxial silicon materials, such as throughout different crystal orientations of the epitaxial silicon materials. The heterogeneously doped epitaxial silicon materials may vary stepwise (e.g., change abruptly) or may vary continuously (e.g., change progressively, such as linearly, parabolically) throughout different portions of the epitaxial silicon materials.

At the process stage shown in FIG. 2A, the apparatus 100 (e.g., an electronic device, a microelectronic device) includes the base material 102, the active areas 104, the STI structures 106, the diffusion regions 110, and the word lines 132, which may be formed by conventional techniques. The active areas 104 and the STI structures 106 are formed adjacent to the base material 102, which has been subjected to previous fabrication acts to form features thereon or therein. Portions (e.g., the diffusion regions 110) of the STI structures 106 are separated from other portions of the STI structures 106 by the insulative spacer material 112. Portions of the active areas 104 underlying the bit line structures 118 are separated from other portions of the active areas 104 by the word lines 132.

The bit line structures 118 are formed adjacent to (e.g., over) exposed portions of the active areas 104 and the STI structures 106. Materials and structures of the bit line structures 118 may be formed by conventional techniques, such as by sequentially forming the materials of the bit contacts 108, the bit lines 114, and the insulative cap material 116. The bit contacts 108 and the bit lines 114 may be formed of an electrically conductive material and the insulative cap material 116 may be formed of an insulative material. In some embodiments, the bit contacts 108 are formed of the epitaxial silicon material, such as the doped epitaxial silicon material. The bit line structures 118 may include additional vertically adjacent materials (not shown), such as a barrier metal material between the bit contacts 108 and the bit lines 114, as well as additional materials and structures (e.g., bit line caps) adjacent to (e.g., over) the insulative cap material 116. The bit line structures 118 may be formed before forming the cell contact structures 130.

The cell contact structures 130 are formed adjacent to (e.g., over) exposed portions of the diffusion regions 110 and the STI structures 106 and may be formed by conventional techniques. The doped epitaxial silicon material 120 may be formed over the STI structures 106 and the diffusion regions 110, as shown in FIG. 2B. The apparatus 100 may include multiple cell contact structures 130, such as cell contact structure 130A, cell contact structure 130B, cell contact structure 130C. The doped epitaxial silicon material 120 may also be formed over the active areas 104 and over the insulative spacer material 112 adjacent to the bit line structures 118. For example, and as shown in FIG. 2A, openings 136 (e.g., contact openings, contact holes) may be formed between laterally adjacent portions of the insulative spacer material 112 on sidewalls of neighboring bit line structures 118. The openings 136 are laterally adjacent to cell contact structure 130A. The openings 136 are formed and defined by sidewalls of the insulative spacer material 112, an upper surface of the active areas 104, an upper surface of the diffusion regions 110, and an upper surface of the STI structures 106. The openings 136 extend to the active areas 104 and the STI structures 106 in the first horizontal direction (e.g., the X-direction). Additional materials of the cell contact structures 130, such as the metal silicide 122, the barrier material 124, and the metal material 126, may be formed adjacent to the doped epitaxial silicon material 120.

As shown in FIG. 2B, the doped epitaxial silicon material 120B′, 120C′ may be formed within the openings 136 and ultimately constitute a portion of cell contact structures 130B, 130C. The epitaxial silicon material in the openings 136 may be doped during the epitaxial growth process, such as with an n-type dopant. The doped epitaxial silicon material 120B′, 120C′ may, for example, include phosphorus as a dopant, forming phosphorus-doped epitaxial silicon material 120B′, 120C′. However, other n-type dopants may be used. The doped epitaxial silicon material 120B′, 120C′ may be formed (e.g., epitaxially grown) adjacent to (e.g., over) the active areas 104, the presence of which enables the doped epitaxial silicon material 120B′, 120C′ to be formed in the monocrystalline (e.g., single crystal) orientation. In other words, the material of the active areas 104 may function as a seed material to orient the crystal form of the doped epitaxial silicon material 120B′, 120C′. The doped epitaxial silicon material 120B′, 120C′ may be formed in different crystal orientations, such as in one or more of the [100] crystal orientation, the [110] crystal orientation, and the [111] crystal orientation, depending on the process conditions used. The doped epitaxial silicon material 120B′, 120C′ may exhibit the desired dopant distribution that results in the desired crystal orientation. The doped epitaxial silicon material 120B′, 120C′ may include a higher ratio of the [110] crystal orientation silicon than the [100] crystal orientation silicon or the [111] crystal orientation silicon. By way of example only, dopant 140 may be relatively more concentrated along sidewalls of the epitaxial silicon material 120B′, 120C′ than on upper surfaces of the epitaxial silicon material, as shown in the X-Y direction of FIGS. 2C-2E. The process conditions may be selected to predominantly form (e.g., selectively form) the doped epitaxial silicon material 120B′, 120C′ in the [110] crystal orientation. The concentration of the dopant 140 in the [110] orientation may be relatively greater than the concentration of the dopant in the [100] orientation or the [111] orientation. Therefore, the doped epitaxial silicon material 120B′, 120C′ may exhibit a higher ratio of the [110] crystal orientation silicon than the [100] crystal orientation silicon or the [111] crystal orientation silicon. By way of example only, greater than about 50% of the doped epitaxial silicon material 120B′, 120C′ may be in the [110] crystal orientation.

The doped epitaxial silicon material 120B′, 120C′ is formed on one or more (e.g., two) of the diffusion regions 110. As shown in FIG. 2B, the uppermost surfaces of the doped epitaxial silicon material 120B′, 120C′ may be substantially planar and include a single material. For illustrative purposes only, the doped epitaxial silicon material 120A is shown as having a rounded uppermost surface and including more than one material in the epitaxial plug 145. However, substantially all of the doped epitaxial silicon materials 120A, 120B′, 120C′ may be planar, or substantially all of the doped epitaxial silicon materials 120A, 120B′, 120C′ may exhibit a rounded uppermost surface.

While a total dopant concentration of the doped epitaxial silicon material 120A, 120B′, 120C′ may be substantially similar to a total dopant concentration of an epitaxial silicon material positioned at a similar location of a conventional apparatus, the doped epitaxial silicon material 120A, 120B′, 120C′ exhibits a different distribution of the dopant 140. The dopant distribution may be relatively higher on the sidewalls of the doped epitaxial silicon material 120A, 120B′, 120C′ compared to corner regions of the doped epitaxial silicon material 120A, 120B′, 120C′. Therefore, the sidewalls of the doped epitaxial silicon material 120A, 120B′, 120C′ include a greater concentration of the dopant 140 than the corner regions. The relatively higher dopant concentration on the sidewalls corresponds to the [110] crystal orientation silicon. The dopant concentration in the doped epitaxial silicon material 120A, 120B′, 120C′ may range from about 3 atomic percent to about 6 atomic percent.

If, for example, the doped epitaxial silicon material 120A, 120B′, 120C′ is doped with phosphorus, the doped epitaxial silicon material 120A, 120B′, 120C′ may include a total phosphorus concentration within a range of from about 1×10¹⁸ atoms/cm³ to about 4.0×10²¹ atoms/cm³ in the sidewalls, or within a range of from about 5×10¹⁹ atoms/cm³ to about 4.3×10²¹ atoms/cm³ in the sidewalls (e.g., the [110] crystal orientation). In contrast, conventional apparatus include a much greater concentration of total phosphorus, such as a range of from about 1×10²¹ atoms/cm³ to about 1×10²¹ atoms/cm³, with the greatest relative dopant concentration in upper surfaces (e.g., the [100] crystal orientation).

While doping the epitaxial silicon material 120B′, 120C′ is described above and illustrated in FIGS. 2A-2C and 2E, the bit contacts 108 may alternatively or additionally be doped as shown in FIGS. 2D, 2E, 2F, and 2G. As shown in the top-down views of FIGS. 2C through 2E, the dopant 140 may be present at different relative concentrations in one or more of the epitaxial silicon material 120 and the bit contacts 108. In the perspective of FIGS. 2C through 2E, the doped epitaxial silicon material 120 and the bit contacts 108 are separated (e.g., spaced apart) from one another by the insulative spacer material 112, the dimensions of which are exaggerated in FIGS. 2C through 2E for illustrative purposes. The relative concentration of the dopant 140 is indicated by the density of atoms of the dopant 140 (indicated by spheres) in FIGS. 2C through 2E, with two spheres (e.g., spheres layered two deep) indicating a higher relative dopant concentration than one sphere (e.g., spheres layered one deep). In other words, the epitaxial silicon material 120 and the bit contacts 108 have a lower relative concentration of the dopant 140 where indicated by a single sphere and a higher relative concentration where indicated by two spheres.

As shown in FIG. 2C, the dopant 140 is present in the doped epitaxial silicon material 120A, 120B′. Alternatively, and as shown in FIG. 2D, the dopant 140 is present in the bit contacts 108, forming doped bit contacts 108′, with a lower relative concentration of dopant 140 indicated by the single spheres and a higher relative concentration indicated by the two spheres. In FIG. 2D, the epitaxial semiconductive material 120 may be a material other than a doped epitaxial silicon material, with the dopant 140 in the bit contacts 108′ formed of and including the doped epitaxial silicon material. In FIG. 2E, the dopant 140 is present in both the doped bit contacts 108′ and the doped epitaxial silicon material 120A, 120B′. The relative dopant distributions shown in FIGS. 2C through 2E are in contrast to dopant distributions in conventional apparatus that include a relatively greater dopant concentration in a [100] or [111] crystal orientation of silicon. For example, in the conventional apparatus, the dopant concentration is relatively greater on the upper surfaces (e.g., top surfaces) and corner regions of epitaxial silicon present in a similar location.

As shown in the top-down view of FIG. 2C, the dopant 140 in the doped epitaxial silicon material 120A, 120B′ is present at a relatively greater concentration in the [110] crystal orientation than in the [100] or [111] crystal orientations. The heavier doping in the [110] crystal orientation is indicated by the two spheres on the sidewalls of the doped epitaxial silicon material 120A, 120B′. By way of example only, the dopant 140 concentration may be relatively greater on the sidewalls of the doped epitaxial silicon material 120A, 120B′ and relatively lower in other regions, such as in a corner region 120′′ of the doped epitaxial silicon material 120A, 120B′. Since the bit contacts 108 and the doped epitaxial silicon material 120A, 120B′ are separated by the insulative spacer material 112, and since the corner regions 120′′ include relatively less dopant 140 than the sidewalls, there is a relatively lower likelihood of an electrical path existing between the bit contacts 108 and the doped epitaxial silicon material 120A, 120B′, which reduces or prevents electrical shorting between contacts.

An additional configuration of the dopant 140 is shown in the top-down view of FIG. 2D. The dopant 140 may exhibit a relatively greater concentration in the [110] crystal orientation of the doped bit contacts 108′ of the bit line structures 118 than in the [100] or [111] crystal orientations. The dopant 140 concentration may be relatively greater on sidewalls of the doped bit contacts 108′ and relatively less at corner regions 108′′ of the bit line structures 118. The bit contacts 108′ may be more heavily doped in the [110] crystal orientation than in the [100] or [111] crystal orientations, as indicated by the two spheres on the sidewalls. By way of example only, the dopant 140 concentration may be relatively greater on the sidewalls of the bit contacts 108′ and relatively lower on other regions, such as on the corner region 108′′. In FIG. 2D, the epitaxial semiconductive material 120 may be the epitaxial silicon material or another semiconductive material. Since the doped bit contacts 108′ and the epitaxial semiconductive material 120 are separated by the insulative spacer material 112, and since the corner regions 108′′ include relatively less dopant 140 than the sidewalls, the doped bit contacts 108′ and the epitaxial semiconductive material 120 may exhibit a relatively low likelihood of shorting.

An additional configuration of the dopant 140 is shown in the top-down view of FIG. 2E, which includes doped epitaxial silicon in both the doped bit contacts 108′ and doped epitaxial silicon material 120A, 120B′. The dopant 140 concentration may be relatively greater on sidewalls of the doped bit contacts 108′ and of the doped epitaxial silicon material 120A, 120B′, and relatively less at the corner regions 108′′, 120′′. The dopant 140 may exhibit a relatively greater concentration in the [110] crystal orientation of the doped epitaxial silicon material 120A, 120B′ than in the [100] or [111] crystal orientations, and the dopant 140 may exhibit a relatively greater concentration in the [110] crystal orientation of the doped bit contacts 108′ than in the [100] or [111] crystal orientations. In other words, the doped epitaxial silicon material 120A, 120B′ and the doped bit contacts 108′ may be more heavily doped in the [110] crystal orientation, as indicated by the two spheres on the sidewalls. By way of example only, the dopant 140 concentration may be relatively greater on the sidewalls of the doped epitaxial silicon material 120A, 120B′ and the doped bit contacts 108′, and relatively lower on other regions, such as on the corner regions 120′′ and the corner regions 108′′. Since the doped bit contacts 108′ and the doped epitaxial silicon material 120A, 120B′ are separated by the insulative spacer material 112 and since the corner regions 120′′ and the corner regions 108′′include relatively less dopant 140, the doped bit contacts 108′ and the doped epitaxial silicon material 120A, 120B′ exhibit a relatively low likelihood of shorting.

Process conditions for forming the doped epitaxial silicon materials of the cell contact structures 130 or the bit line structures 118 may be selected to achieve the desired dopant distribution, with the desired dopant distribution depending on desired electrical performance properties of the apparatus 100. The dopant concentration in the epitaxial silicon materials may be determined by conventional techniques including, but not limited to, atom probe tomography (APT) or transmission electron microscopy (TEM). The desired dopant distribution in the [110] crystal orientation may be achieved by appropriately selecting one or more of temperature, pressure, duration, energy, angle, gas flow rates of precursor compounds, selection of precursor compounds, etc., during the formation of the doped epitaxial silicon materials.

By way of example only, the concentration of dopant 140 may be relatively greater in the [110] crystal orientation when a relatively high temperature is used. The temperature for forming the doped epitaxial silicon materials may range from about 300° C. to about 900° C., such as from about 650° C. to about 690° C., from about 660° C. to about 690° C., from about 670° C. to about 690° C., from about 680° C. to about 690° C., from about 650° C. to about 680° C., from about 650° C. to about 670° C., or from about 650° C. to about 660° C.

The concentration of dopant 140 may be greater in the [110] crystal orientation when a relatively high pressure is used. The pressure for forming the doped epitaxial silicon materials may range from about 5 Torr to about 600 Torr (from about 0.67 kPa to about 79.99 kPa), such as from about 200 Torr to about 300 Torr, from about 200 Torr to about 250 Torr, from about 210 Torr to about 250 Torr, from about 220 Torr to about 250 Torr, from about 230 Torr to about 250 Torr, from about 240 Torr to about 250 Torr, from about 250 Torr to about 300 Torr, from about 260 Torr to about 300 Torr, from about 270 Torr to about 300 Torr, from about 280 Torr to about 300 Torr, from about 290 Torr to about 300 Torr, from about 300 Torr to about 400 Torr, from about 400 Torr to about 500 Torr, or from about 500 Torr to about 600 Torr. Out of the process conditions, selecting the pressure may provide the greatest effect on achieving the desired selective dopant distribution in the [110] crystal orientation of silicon.

The choice of precursor compounds used to form the epitaxial silicon material may also affect the selective distribution of the dopant 140. By way of example only, if a phosphorus doped, epitaxial silicon material is to be formed, silane, disilane, or dichlorosilane (DSC) may be used as a silicon precursor compound and phosphene may be used as a phosphorus precursor compound. Relative amounts of the precursor compounds, such as the silicon precursor compound and the phosphorus precursor compound, may be selected depending on the desired dopant concentration.

The concentration of dopant 140 (e.g., phosphorus) may be greater in the [110] crystal orientation of the epitaxial silicon material when a relatively high concentration of the dopant precursor compound is used, a relatively low concentration of the silicon precursor compound is used, and a relatively low concentration of an etchant (e.g., HCl) is used. By way of example only, the silicon precursor compound may be used at a flow rate of from about 450 standard cubic centimeters per minute (sccm) to about 650 sccm, such as from about 450 sccm to about 600 sccm, from about 450 sccm to about 550 sccm, from about 450 sccm to about 500 sccm, from about 500 sccm to about 650 sccm, from about 550 sccm to about 650 sccm, or from about 600 sccm to about 650 sccm. By way of example only, the phosphorus precursor compound may be used at a flow rate of from about 100 sccm to about 300 sccm, such as from about 100 sccm to about 250 sccm, from about 100 sccm to about 200 sccm, from about 100 sccm to about 150 sccm, from about 150 sccm to about 300 sccm, from about 200 sccm to about 300 sccm, or from about 250 sccm to about 300 sccm. If an etchant is used, the flow rate of the etchant may be from about 95 sccm to about 145 sccm, such as from about 95 sccm to about 140 sccm, from about 95 sccm to about 135 sccm, from about 95 sccm to about 130 sccm, from about 95 sccm to about 125 sccm, from about 95 sccm to about 120 sccm, from about 95 sccm to about 115 sccm, from about 95 sccm to about 110 sccm, from about 95 sccm to about 105 sccm, from about 95 sccm to about 100 sccm, from about 100 sccm to about 145 sccm, from about 105 sccm to about 145 sccm, from about 110 sccm to about 145 sccm, from about 115 sccm to about 145 sccm, from about 120 sccm to about 145 sccm, from about 125 sccm to about 145 sccm, from about 130 sccm to about 145 sccm, from about 135 sccm to about 145 sccm, or from about 140 sccm to about 145 sccm.

Optional treatment acts, such as annealing, rapid thermal annealing, etc., may also be utilized before or after forming the doped epitaxial silicon materials. The doped epitaxial silicon material may be formed in small increments (e.g., a portion at a time) and various optional annealing treatments may be utilized for each increment.

The bit lines 114 and insulative cap materials 116 may be formed before or after forming the doped epitaxial silicon material 120B′, 120C′ to form the cell contact structures 130B, 130C of the apparatus 100, which may include the apparatus 100A shown in FIG. 1, the apparatus 100B shown in FIG. 2F, or the apparatus 100C shown in FIG. 2G. The apparatus 100 refers collectively to apparatus 100A, apparatus 100B, or apparatus 100C. The apparatus 100A includes the dopant distribution of FIG. 2C, the apparatus 100B includes the dopant distribution of FIG. 2D, and the apparatus 100C includes the dopant distribution of FIG. 2E. The apparatus 100B, 100C including the dopant distributions of FIG. 2D or 2E, respectively, are similar to that shown for apparatus 100A, except that the dopant 140 is present in the doped bit contacts 108′ or in both the doped bit contacts 108′ and the doped epitaxial silicon material 120A, 120B′, as shown in FIGS. 2F and 2G, respectively.

During use and operation of the apparatus 100 (e.g., apparatus 100A, apparatus 100B, apparatus 100C), a degree of electrical shorting between the bit contacts 108 and the cell contacts 128 of the apparatus 100 is reduced compared to a degree of electrical shorting observed in conventional apparatus that lack the doped epitaxial silicon material having the higher dopant ratio in the [110] crystal orientation. The decreased electrical shorting may be due to an electrical path between the bit contacts 108 and the epitaxial semiconductive material 120 in the apparatus 100 no longer being present. The reduced electrical shorting is achieved in the apparatus 100 without decreasing resistance (e.g., contact resistance). The reduced electrical shorting enables the apparatus 100 to be produced at a relatively higher yield than apparatus produced by conventional processes. In addition, when doped epitaxial silicon material is used as the epitaxial semiconductive material 120, the resulting epitaxial silicon plug 145 in the apparatus 100 is highly doped, which enables increased thermal stability in a small contact area compared to a polysilicon plug present in a similar location of conventional apparatus. While the reduced electrical shorting and other electrical performance properties are achieved when the dopant is phosphorus (e.g., the epitaxial semiconductive material 120 is phosphorus doped epitaxial silicon), the apparatus 100 may achieve similar electrical performance properties when the dopant includes arsenic, antimony, or a combination thereof with phosphorus.

Without being bound by any theory, the process conditions for forming the doped epitaxial silicon materials are believed to affect dopant segregation, which in turn reduces electrical shorting between the bit line structures 118 and the cell contact structures 130 of the apparatus 100. The process conditions facilitate one or more of increased concentration and heterogeneous distribution of the dopants to improve the dopant segregation at grain boundaries. Crystallinity of the materials also affect the dopant segregation at the grain boundaries, resulting in varying levels of diffusion (e.g., distribution) of the dopants within the doped epitaxial silicon materials. Adjusting the process conditions is also believed to affect charge density between the doped epitaxial silicon materials of one or more of the bit line structures 118 and the cell contact structures 130. The charge density is reduced by tailoring the dopant density (e.g., dopant profile) within the doped epitaxial silicon materials so that corner regions of the doped epitaxial silicon materials, as best illustrated in FIGS. 2C-2E, include a relatively low charge density, which results in a low likelihood of electrical shorting between the bit contacts 108 and the cell contacts 128. By reducing the charge density between the doped epitaxial silicon materials of the bit line structures 118 and the cell contact structures 130, the conductive features exhibit reduced electrical shorting even though the conductive features may be closely spaced. The reduced charge density is achieved even when the bit contacts 108 and the epitaxial semiconductive material 120 face one another. The dopant distribution in the doped epitaxial silicon materials may also provide improved capacitance between the bit contacts 108 and the cell contacts 128. In addition, digit line capacitance may remain substantially unaffected while maintaining resistance and drive current of the apparatus 100. By reallocating the dopant distribution in the desired crystal orientation of the doped epitaxial silicon materials, the electrical shorting between the contacts may be reduced relative to electrical shorting observed in similarly located contacts of conventional apparatus, which lack the dopant distribution in the desired crystal orientation or that include polycrystalline silicon features.

In conventional apparatus, similarly located structures (e.g., corresponding to the bit contacts 108 and the epitaxial semiconductive material 120) may be formed of a polycrystalline material, such as polycrystalline silicon, or of doped epitaxial silicon lacking the dopant predominantly in the desired [110] crystal orientation. In conventional apparatus having polycrystalline silicon in similarly located structures, the polycrystalline silicon does not exhibit similar properties that enable selectively doping a desired crystal orientation of the material. In conventional apparatus having doped epitaxial silicon lacking the dopant predominantly in the desired [110] crystal orientation in similarly located structures, the apparatus does not exhibit desired electrical performance characteristics. Electrical shorting in these conventional apparatus is due to the presence of the electrical path between the similarly-located structures (e.g., between contacts), with increased charge density between the similarly-located structures.

Accordingly disclosed is an apparatus comprising a memory array comprising word lines, bit lines, and memory cells. One or more of the memory cells is coupled to an associated word line and an associated bit line and comprises active areas and shallow trench isolation (STI) structures adjacent to a base material. The word lines are in the active areas and STI structures and bit line structures are adjacent to the active areas and the STI structures and oriented perpendicular to the word lines. The bit line structures comprise bit lines and bit contacts. Cell contact structures are laterally adjacent to the bit line structures and comprise cell contacts comprising an epitaxial semiconductive material. One or more of the bit contacts and the epitaxial semiconductive material comprise a doped epitaxial silicon material, the doped epitaxial silicon material exhibiting a relatively greater dopant concentration in a [110] crystal orientation than in a [100] or [111] crystal orientation.

Accordingly disclosed is an apparatus comprising memory cells coupled to associated access lines and to associated digit lines. The memory cells comprise bit line structures and cell contact structures laterally adjacent to the bit line structures. At least one of the bit line structures and the cell contact structures comprise a doped epitaxial silicon material exhibiting a relatively greater dopant ratio in a [110] crystal orientation than in a [100] or [111] crystal orientation.

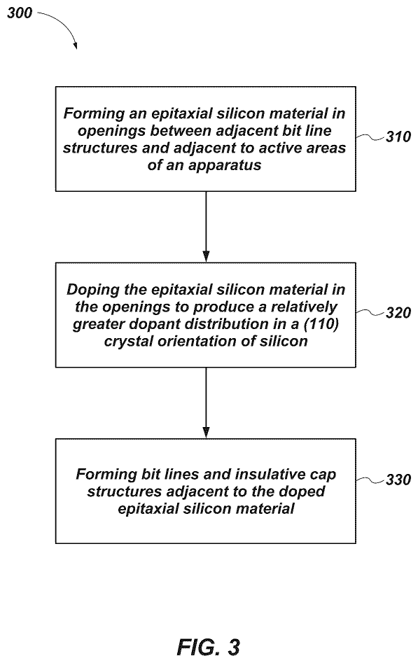

FIG. 3 is a flowchart of a method 300 of forming an apparatus according to embodiments of the disclosure. The method 300 includes forming 310 an epitaxial silicon material in openings between adjacent bit line structures and adjacent to active areas of the apparatus. The method 300 includes doping 320 the epitaxial silicon material. The doped epitaxial silicon material includes a relatively higher ratio of [110] crystal orientation silicon than [100] crystal orientation silicon or [111] crystal orientation silicon. The method 300 includes forming 330 bit lines and insulative cap structures adjacent to the doped epitaxial silicon material. As previously described, the doped epitaxial silicon material may be present in one or more of the bit contacts 108 and the cell contacts 128.

Accordingly disclosed is a method of forming an apparatus comprising forming bit line structures comprising bit lines and bit line contacts on a base material. The base material comprises active areas and shallow trench isolation (STI) structures therein and the bit line contacts comprise a first epitaxial silicon material. A second epitaxial silicon material is formed laterally adjacent to the bit line structures and vertically adjacent to the active areas and STI structures. One or more of the first epitaxial silicon material and the second epitaxial silicon is doped, the one or more of the first epitaxial silicon material and the second epitaxial silicon exhibiting a relatively greater dopant concentration in a [110] crystal orientation than in a [100] or [111] crystal orientation. A metal material is formed vertically adjacent to the second epitaxial silicon material to form cell contact structures comprising cell contacts.

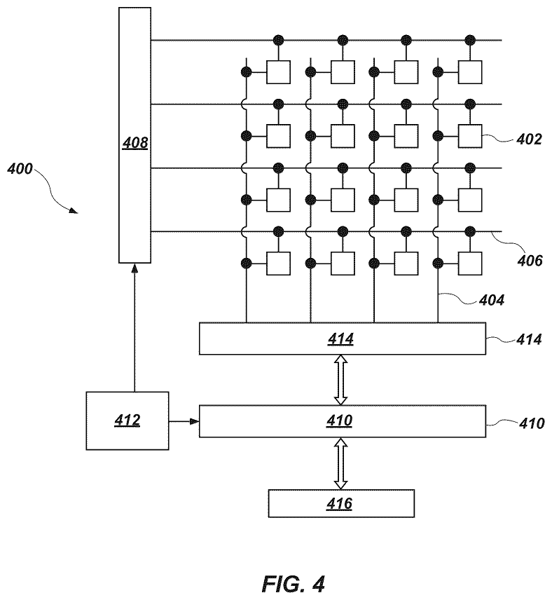

Additional processing acts may subsequently be conducted to form an electronic device that includes the apparatus 100. The apparatus 100 (e.g., apparatus 100A, 100B, 100C) may be subjected to additional processing acts to form an electronic device 400 (e.g., a memory device) including one or more of apparatus 100A, 100B, 100C. Such additional processing may employ conventional processes and conventional processing equipment. The electronic device 400 may include, for example, embodiments of the apparatus 100A, 100B, 100C previously described. As shown in FIG. 4, the electronic device 400 may include memory cells 402, digit lines 404 (e.g., bit lines), word lines 406 (e.g., access lines), a row decoder 408, a column decoder 410, a memory controller 412, a sense device 414, and an input/output device 416.

The memory cells 402 of the electronic device 400 are programmable to at least two different logic states (e.g., logic 0 and logic 1). Each memory cell 402 may individually include a storage device (e.g., a capacitor) and an access device (e.g., a transistor) and the apparatus 100 according to embodiments of the disclosure. The capacitor stores a charge representative of the programmable logic state (e.g., a charged capacitor may represent a first logic state, such as a logic 1; and an uncharged capacitor may represent a second logic state, such as a logic 0) of the memory cell 402. The transistor grants access to the capacitor upon application (e.g., by way of one of the word lines 406) of a minimum threshold voltage to a semiconductive channel thereof for operations (e.g., reading, writing, rewriting) on the capacitor.

The digit lines 404 are connected to the capacitors of the memory cells 402 by way of the transistors of the memory cells 402. The word lines 406 extend perpendicular to the digit lines 404 and are connected to gates of the transistors of the memory cells 402. Operations may be performed on the memory cells 402 by activating appropriate digit lines 404 and word lines 406. Activating a digit line 404 or a word line 406 may include applying a voltage potential to the digit line 404 or the word line 406. Each column of memory cells 402 may individually be connected to one of the digit lines 404, and each row of the memory cells 402 may individually be connected to one of the word lines 406. Individual memory cells 402 may be addressed and accessed through the intersections (e.g., cross points) of the digit lines 404 and the word lines 406.

The memory controller 412 may control the operations of the memory cells 402 through various components, including the row decoder 408, the column decoder 410, and the sense device 414. The memory controller 412 may generate row address signals that are directed to the row decoder 408 to activate (e.g., apply a voltage potential to) predetermined word lines 406, and may generate column address signals that are directed to the column decoder 410 to activate (e.g., apply a voltage potential to) predetermined digit lines 404. The memory controller 412 may also generate and control various voltage potentials employed during the operation of the electronic device 400. In general, the amplitude, shape, and/or duration of an applied voltage may be adjusted (e.g., varied), and may be different for various operations of the electronic device 400.

During use and operation of the electronic device 400, after being accessed, a memory cell 402 may be read (e.g., sensed) by the sense device 414. The sense device 414 may compare a signal (e.g., a voltage) of an appropriate digit line 404 to a reference signal in order to determine the logic state of the memory cell 402. If, for example, the digit line 404 has a higher voltage than the reference voltage, the sense device 414 may determine that the stored logic state of the memory cell 402 is a logic 1, and vice versa. The sense device 414 may include transistors and amplifiers to detect and amplify a difference in the signals. The detected logic state of a memory cell 402 may be output through the column decoder 410 to the input/output device 416. In addition, a memory cell 402 may be set (e.g., written) by similarly activating an appropriate word line 406 and an appropriate digit line 404 of the electronic device 400. By controlling the digit line 404 while the word line 406 is activated, the memory cell 402 may be set (e.g., a logic value may be stored in the memory cell 402). The column decoder 410 may accept data from the input/output device 416 to be written to the memory cells 402. Furthermore, a memory cell 402 may also be refreshed (e.g., recharged) by reading the memory cell 402. The read operation will place the contents of the memory cell 402 on the appropriate digit line 404, which is then pulled up to full level (e.g., full charge or discharge) by the sense device 414. When the word line 406 associated with the memory cell 402 is deactivated, all of memory cells 402 in the row associated with the word line 406 are restored to full charge or discharge.

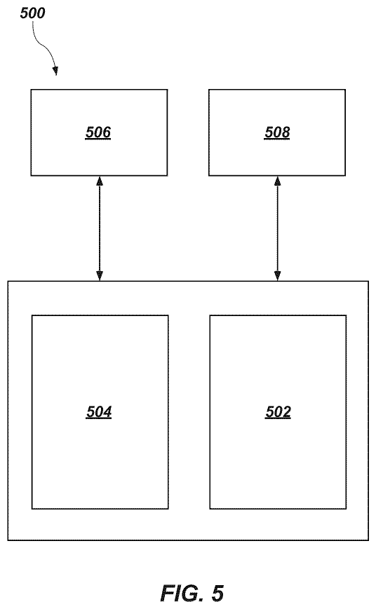

The apparatus 100 (e.g., 100A, 100B, 100C) according to embodiments of the disclosure may be used in embodiments of electronic systems of the disclosure. For example, FIG. 5 is a block diagram of an illustrative electronic system 500 according to embodiments of disclosure. The electronic system 500 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 500 includes at least one electronic device 400. The electronic device 400 may include, for example, one or more of the apparatus 100A, 100B, 100C previously described herein. The electronic system 500 may further include at least one electronic signal processor device 504 (often referred to as a “microprocessor”). The electronic signal processor device 504 may, optionally, include one or more of the apparatus 100A, 100B, 100C previously described herein. The electronic system 500 may further include one or more input devices 506 for inputting information into the electronic system 500 by a user, such as, for example, a mouse or other pointing device, a keyboard, a touchpad, a button, or a control panel. The electronic system 500 may further include one or more output devices 508 for outputting information (e.g., visual or audio output) to a user such as, for example, a monitor, a display, a printer, an audio output jack, a speaker, etc. In some embodiments, the input device 506 and the output device 508 may comprise a single touchscreen device that can be used both to input information to the electronic system 500 and to output visual information to a user. The input device 506 and the output device 508 may communicate electrically with one or more of the electronic device 502 and the electronic signal processor device 504.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. An apparatus, comprising:
a memory array comprising word lines, bit lines, and memory cells, one or more of the memory cells coupled to an associated word line and an associated bit line and one or more of the memory cells comprising:
active areas and shallow trench isolation (STI) structures adjacent to a base material;
the word lines in the active areas and STI structures;
bit line structures adjacent to the active areas and the STI structures and oriented perpendicular to the word lines, the bit line structures comprising bit lines and bit contacts; and
cell contact structures laterally adjacent to the bit line structures, the cell contact structures comprising cell contacts comprising an epitaxial semiconductive material,
one or more of the bit contacts and the epitaxial semiconductive material comprising a doped epitaxial silicon material, the doped epitaxial silicon material exhibiting a relatively greater dopant concentration in a [110] crystal orientation than in a [100] or [111] crystal orientation.

2. The apparatus of claim 1, wherein the epitaxial semiconductive material of the cell contact structures comprises the doped epitaxial silicon material exhibiting the relatively greater dopant concentration in the [110] crystal orientation.

3. The apparatus of claim 2, wherein sidewalls of the doped epitaxial silicon material of the cell contact structures exhibit a greater dopant concentration than corner regions of the cell contact structures.

4. The apparatus of claim 1, wherein the bit contacts comprise the doped epitaxial silicon material exhibiting the relatively greater dopant concentration in the [110] crystal orientation.

5. The apparatus of claim 4, wherein sidewalls of the doped epitaxial silicon material of the bit contacts exhibit a greater dopant concentration than corner regions of the bit contacts.

6. The apparatus of claim 1, wherein the doped epitaxial silicon material comprises phosphorus doped epitaxial silicon.

7. The apparatus of claim 1, wherein the doped epitaxial silicon material comprises arsenic doped epitaxial silicon, antimony doped epitaxial silicon, a combination thereof, or a combination thereof with phosphorus doped epitaxial silicon.

8. The apparatus of claim 1, further comprising an insulative material between corner regions of the bit contacts and of the epitaxial semiconductive material of the cell contact structures.

9. An apparatus, comprising:
memory cells coupled to associated access lines and to associated digit lines, the memory cells comprising bit line structures and cell contact structures laterally adjacent to the bit line structures, at least one of the bit line structures and the cell contact structures comprising a doped epitaxial silicon material exhibiting a relatively greater dopant ratio in a [110] crystal orientation than in a [100] crystal orientation or a [111] crystal orientation.

10. The apparatus of claim 9, wherein the doped epitaxial silicon material in at least one of the bit line structures and the cell contact structures exhibits a relatively greater dopant ratio in the [110] crystal orientation than in the [100] crystal orientation.

11. The apparatus of claim 9, wherein a dopant of the doped epitaxial silicon material comprises phosphorus and the [110] crystal orientation comprises a total phosphorus concentration within a range of from about 5×10¹⁹ atoms/cm³ to about 4.3×10²¹ atoms/cm³.

12. The apparatus of claim 9, wherein a dopant of the doped epitaxial silicon material comprises phosphorus and the [110] crystal orientation comprises a total phosphorus concentration within a range of from about 1×10¹⁸ atoms/cm³ to about 4.0×10²¹ atoms/cm³.

13. The apparatus of claim 9, wherein corner regions of the bit line structures and of the cell contact structures exhibit relatively less dopant than sidewalls of the bit line structures and the cell contact structures.

14. A method of forming an apparatus, comprising:
forming bit line structures comprising bit lines and bit line contacts on a base material, the base material comprising active areas and shallow trench isolation (STI) structures therein and the bit line contacts comprising a first epitaxial silicon material;
forming a second epitaxial silicon material laterally adjacent to the bit line structures and vertically adjacent to the active areas and STI structures;
doping one or more of the first epitaxial silicon material and the second epitaxial silicon material, the one or more of the first epitaxial silicon material and the second epitaxial silicon material exhibiting a relatively greater dopant concentration in a [110] crystal orientation than in a [100] crystal orientation or a [111] crystal orientation; and
forming a metal material vertically adjacent to the second epitaxial silicon material to form cell contact structures comprising cell contacts.

15. The method of claim 14, wherein doping one or more of the first epitaxial silicon material and the second epitaxial silicon material comprises forming one or more of the first epitaxial silicon material and the second epitaxial silicon material comprising phosphorus, antimony, arsenic, or a combination thereof.

16. The method of claim 14, wherein doping one or more of the first epitaxial silicon material and the second epitaxial silicon material comprises forming one or more of the first epitaxial silicon material and the second epitaxial silicon material comprising phosphorus.

17. The method of claim 16, wherein forming one or more of the first epitaxial silicon material and the second epitaxial silicon material comprising phosphorus comprises forming one or more of a phosphorus doped first epitaxial silicon material and a phosphorus doped second epitaxial silicon material at a pressure within a range of from about 0.67 kPa to about 79.99 kPa.

18. The method of claim 16, wherein forming one or more of the first epitaxial silicon material and the second epitaxial silicon material comprising phosphorus comprises forming one or more of a phosphorus doped first epitaxial silicon material and a phosphorus doped second epitaxial silicon material at a temperature of from about 300° C. to about 900° C..

19. The method of claim 16, wherein forming one or more of the first epitaxial silicon material and the second epitaxial silicon material comprising phosphorus comprises forming the first epitaxial silicon material and the second epitaxial silicon material from a silicon precursor and a phosphorus precursor.

20. The method of claim 19, wherein forming the first epitaxial silicon material and the second epitaxial silicon material from a silicon precursor and a phosphorus precursor comprises using phosgene as the phosphorus precursor, the phosphorus selectively incorporated into the [110] silicon crystal orientation.
